(19) United States
(12) Patent Application Publication
(10) Pub. No.: US 2026/0092990 A1
(43) Pub. Date: Apr. 2, 2026

(54) SENSOR PACKAGE WITH TMR SENSOR CHIP

(71) Applicant: Infineon Technologies AG, Neubiberg (DE)

(72) Inventors: Horst THEUSS, Wenzenbach (DE); Ingrid MAUS, Regensburg (DE); Johannes GÜTTINGER, Lind ob Velden (AT); Massimiliano ZILLI, Udine (IT)

(21) Appl. No.: 19/289,833

(22) Filed: Aug. 4, 2025

(30) Foreign Application Priority Data
Aug. 26, 2024 (DE) 102024124329.5

(51) Int. Cl. G01R 33/00; G01R 33/09

(52) U.S. Cl. CPC G01R 33/0076; G01R 33/0047; G01R 33/0052; G01R 33/098

(57) ABSTRACT

A sensor package is proposed, including a tunneling magnetoresistance (TMR) sensor chip and a buffer layer having a modulus of elasticity of less than 1 GPa at a temperature of 20° C. The buffer layer is fitted on and/or under the TMR sensor chip.

### CROSS REFERENCE TO RELATED APPLICATION

This application claims priority to Germany Patent Application No. 102024124329.5 filed on Aug. 26, 2024, the content of which is incorporated by reference herein in its entirety.

### TECHNICAL FIELD

The present disclosure relates in general to magnetoresistive sensors and in particular sensor packages with tunneling magnetoresistance (TMR) sensors.

### BACKGROUND

Mechanical stresses are a challenge in the development and production of xMR sensors, particularly TMR sensors. The abbreviation “xMR” stands for various types of magnetoresistive effects, wherein the “x” is used as a placeholder for the specific effect. The most common types include AMR (anisotropic magnetoresistance), GMR (giant magnetoresistance) and TMR (tunneling magnetoresistance). In the case of AMR, the resistance of a material changes depending on the orientation of the magnetic domains relative to the current direction. GMR occurs in thin layers made from alternating magnetic and non-magnetic materials and leads to a large change in the electrical resistance depending on an external magnetic field. TMR describes a change in the electrical resistance due to tunneling of electrons through a thin insulating layer between two ferromagnetic layers. xMR sensors are used in a wide range of applications, including in the automotive industry, in medicine, in data storage, and in industrial automation. They offer advantages such as high sensitivity, small size and the capability to measure both static and dynamic magnetic fields.

xMR sensors can be produced in packages. A package is a protective case that protects the sensor from external influences such as mechanical loads, moisture and temperature fluctuations. Packaging can be important for xMR sensors, such as AMR, GMR and TMR sensors, as it can protect the sensitive magnetoresistive layers from damage and ensure their functionality. Suitable packaging can also improve heat dissipation and increase the long-term reliability of the sensor. In addition, the package allows the sensor to be easily integrated into various systems and applications, which is advantageous in fields such as the automotive industry, medical technology and industrial automation.

Steps for mounting packages and modules can lead to considerable mechanical stresses on a sensor die, which are caused by thermal incompatibilities, material shrinkage and temperature fluctuations. These stresses can considerably impair the performance of the sensitive TMR sensors. Speed sensors are particularly affected, but these challenges are also encountered in other TMR applications, such as angle, position and current sensors. Particularly in the case of TMR sensors which are used in the automotive industry and in industrial automation, it is important to minimize such negative effects to ensure the performance and longevity of the sensors.

Thus, there is a need for effective solutions to reduce mechanical stresses and increase the robustness and reliability of TMR sensors at the same time.

### SUMMARY

This need is addressed by devices and methods as claimed in the accompanying claims.

According to a first aspect of the present disclosure, a sensor package is proposed. The sensor package includes a TMR sensor chip (die) having one or more TMR resistors. The sensor package further includes a buffer layer (or one or more buffer layers) with a lower modulus of elasticity than the TMR sensor chip (and other components of the sensor package). The buffer layer is fitted on and/or under the TMR sensor chip to reduce mechanical stresses on the TMR sensor chip or on the TMR resistors.

The sensor package contains a TMR sensor chip having one or more TMR resistors. The package includes one or more buffer layers, which are respectively fitted on and/or under (e.g., atop or underneath) the TMR sensor chip and have a lower modulus of elasticity than the TMR sensor chip itself. The buffer layers are used to reduce mechanical stresses which are acting on the TMR sensor chip and the TMR resistors. One advantage is that the reduction of mechanical stresses can improve accuracy and service life of the TMR sensor. In particular, the sensitivity of the sensor to external forces can be reduced, which leads to measurements that are more stable and more precise.

According to some example implementations, the buffer layer has a modulus of elasticity of less than 1 gigapascal (GPa), preferably less than 0.5 GPa and even more preferably less than 0.2 GPa at a temperature of 20° C. The low modulus of elasticity should preferably be maintained over a temperature range of room temperature (20° C.) to 150° C. This means that a material of the buffer layer is relatively flexible and deforms under load instead of remaining rigid. The low modulus of elasticity is maintained over a wide temperature range, from room temperature to 150° C. This ensures that the buffer layer retains its capability to absorb mechanical stresses and thus protect the TMR sensor chip, even at high temperatures. One advantage is that the TMR sensor chip and its TMR resistors are reliably protected from mechanical loads even in the case of changing temperatures. As a result, the functionality of the sensor remains stable, which is important particularly in applications that are exposed to large temperature fluctuations.

According to some example implementations, the buffer layer includes a silicone-based material. This means that the main material of the buffer layer consists of silicone. Silicone is known for its high flexibility, temperature resistance and resistance to environmental factors such as moisture and chemicals. One advantage of using a silicone-based material in the buffer layer is that it enables effective damping of mechanical stresses. This contributes to protecting a structural integrity and the functionality of the TMR sensor chip, particularly in environments in which the sensor is exposed to mechanical shocks or temperature fluctuations.

According to some example implementations, the buffer layer includes a silicone adhesive. This means that the layer consists of a silicone adhesive that fulfills both the function of a buffer and that of an adhesive bond. The silicone adhesive is used to hold the various components in the sensor together while acting as a damping layer at the same time. One advantage of using a silicone adhesive consists in it not only absorbing mechanical stresses, but also producing a strong, flexible bond between the sensor components. This can improve the stability and longevity of the sensor, as it can compensate movements and thermal expansions within the sensor without cracks or damage occurring.

According to some example implementations, the buffer layer has a thickness in the range of 50-150 micrometers (μm). One advantage of this specific thickness consists in it offering an optimum balance between flexibility and mechanical stability. Such a thickness is sufficient to effectively absorb mechanical stresses and at the same time thin enough not to adversely affect the compact design of the sensor. This leads to an improved protective effect for the sensor chip, without adversely affecting the sensitivity or the miniaturization options of the sensor.

According to some example implementations, one or more spacers are embedded into the buffer layer. This means that small structural elements can be integrated within the buffer layer to ensure a constant spacing between the buffer layer and other components of the sensor. One advantage of this design consists in it being possible for the spacers to ensure an even thickness of the buffer layer, as a result of which a consistent damping property is achieved over an entire surface. This can contribute to distributing mechanical loads evenly and preventing load peaks at certain points, which could damage the sensor. The reliability and service life of the sensor can be increased as a result.

According to some example implementations, the spacers are of spherical design. This means that spacers can have a round, spherical shape. One advantage of a spherical shape of the spacers consists in them enabling an even distribution of mechanical stresses in the buffer layer. The round shape minimizes sharp edges or concentration points that could otherwise lead to uneven loading and potential damage.

According to some example implementations, the spacers include the material silicon oxide. This means that the spacers consist of or contain silicon oxide. Silicon oxide, also known as quartz, is a stable, solid material which is used in microelectronics. One advantage of using silicon oxide for the spacers consists in this material having a high hardness and stability. As a result, the spacers become resistant to mechanical loads, which makes it possible to maintain constant spacing. Silicon oxide is also chemically inert and does not react with other materials, which increases the longevity and reliability of the sensor under various operating conditions.

According to some example implementations, the TMR sensor chip is arranged on a lead frame. The buffer layer is arranged between the lead frame and the TMR sensor chip. This means that the TMR sensor chip can be mounted on a so-called lead frame, a carrier frame which is used as a mechanical and electrical connection unit. The buffer layer is located between the lead frame and the TMR sensor chip and separates these two components from each other. One advantage of this arrangement is that the buffer layer functions as a buffer and counteracts and dampens mechanical stresses or vibrations that could be transferred from the lead frame to the sensor chip. As a result, the TMR sensor chip can be protected from mechanical damage, which increases the stability and reliability of the sensor. This arrangement can also contribute to compensating thermal expansions which can form due to temperature differences, as a result of which the performance of the sensor remains consistent over a wide temperature range.

According to some example implementations, the sensor package further includes a potting material within which the TMR sensor chip and the buffer layer are potted. The modulus of elasticity of the buffer layer is lower than a modulus of elasticity of the potting material. This means that the sensor package additionally contains a potting material which surrounds and embeds the TMR sensor chip and the buffer layer. The potting material is harder and stiffer than the buffer layer in this case, because it has a higher modulus of elasticity. One advantage of this design consists in the softer buffer layer between the harder potting material and the sensitive sensor chip absorbing and damping mechanical stresses. This protects the sensor chip from cracks and other damage that could come about due to mechanical loads. The harder potting material simultaneously offers a robust outer layer that protects the entire sensor from external influences such as moisture, dust and physical shocks. This combination can ensure a higher reliability and longevity of the sensor, particularly in harsh environments.

According to some example implementations, the buffer layer is arranged between the TMR sensor chip and the potting material. This means that the buffer layer can be positioned as a type of intermediate layer between the TMR sensor chip and the surrounding potting material. This arrangement places the buffer layer directly between the sensor chip and the harder outer potting material. One advantage of this configuration is that the buffer layer is used as a buffer which counteracts and absorbs mechanical stresses or shocks that could be caused by the hard potting material. As a result, the sensitive TMR sensor chip is protected from mechanical loads that could lead to damage or malfunctions. In addition, the buffer layer helps to compensate thermal stresses that could arise due to different coefficients of expansion of the potting material and the sensor chip in the event of temperature fluctuations.

According to some example implementations, the buffer layer is arranged on the TMR sensor chip and the TMR sensor chip is arranged on a lead frame. This means that the buffer layer can be fitted on the top side of the TMR sensor chip, while the underside of the sensor chip itself is attached to a lead frame. One advantage of this arrangement consists in the buffer layer protecting the sensor chip from above and being able to absorb mechanical shocks or pressure that could act on the top side of the chip. At the same time, mounting the sensor chip on the lead frame ensures stable mechanical support and allows easy integration into further electronic systems.

According to some example implementations, a first buffer layer is arranged on the TMR sensor chip and a second buffer layer is arranged below the TMR sensor chip, between the TMR sensor chip and the lead frame. This means that a first buffer layer is positioned on the top side of the TMR sensor chip and a second buffer layer is positioned below the TMR sensor chip, between the chip and the lead frame. One advantage of this arrangement is that the TMR sensor chip is protected, both from above and from below, by the buffer layers. This double damping layer helps to effectively absorb and mitigate mechanical stresses and vibrations that could act on the chip from different directions. As a result, the sensor chip can be protected comprehensively, which leads to greater resistance to mechanical loads and thus to improved reliability and longevity of the sensor.

According to some example implementations, a lateral extent of the buffer layer is smaller than a lateral extent of the TMR sensor chip. This means that the lateral extent of the buffer layer is smaller than the lateral extent of the TMR sensor chip. In other words, the buffer layer does not cover the entire surface of the chip, but rather extends only over a portion of it. One advantage of this design consists in it being possible to position the buffer layer in a targeted manner where the strongest mechanical loads occur or where the protection of the chip is particularly important. This selective coverage can contribute to reducing material and production costs while simultaneously ensuring the necessary protection of the chip. In addition, the partial coverage can improve heat dissipation in that it exposes areas of the chip, as a result of which overheating is avoided.

According to a further aspect of the present disclosure, a method for producing a sensor package is proposed. The method includes providing a TMR sensor chip. The method further includes providing a buffer layer, on and/or under the TMR sensor chip, having a modulus of elasticity of less than 1 GPa at a temperature of 20° C. According to some example implementations, the buffer layer has a modulus of elasticity of less than 0.5 GPa and preferably of less than 0.2 GPa at a temperature of 20° C.

According to some example implementations, when providing the buffer layer, the buffer layer is applied directly to a wafer before individual TMR sensor chips are separated from each other. This means that the buffer layer can be applied to the entire wafer, which contains a plurality of TMR sensor chips, before these chips are separated from each other and singulated. One advantage of this method is that the buffer layer can be applied to all chips in a single production step, which makes the production process more efficient and less expensive. In addition, this approach ensures even and consistent application of the buffer layer to all chips, as a result of which the quality and reliability of the individual sensors can be improved.

According to some example implementations, when providing the buffer layer, the buffer layer is applied after the TMR sensor chip has been attached to a substrate or lead frame. This means that the buffer layer is only applied to the TMR sensor chip after the chip has already been mounted on a substrate or lead frame. One advantage of this approach is that it enables precise positioning and adjustment of the buffer layer, as the layer is applied directly to the mounted chip. This can ensure that the buffer layer is applied exactly at the points where protection from mechanical loads is necessary. In addition, this method can help optimize production steps by applying the buffer layer to pre-mounted components, which ensures even coverage and improved adhesion on the chip and the lead frame.

According to some example implementations, providing the buffer layer includes dispensing, jetting or screen printing of the buffer layer. These methods are techniques for applying precise quantities of materials to specific areas. One advantage of these methods lies in the high accuracy and control they offer when applying the buffer layer. As a result, the thickness and position of the buffer layer can be controlled precisely, which ensures an even and consistent protective layer.

According to some example implementations, the method further includes potting the TMR sensor chip and the buffer layer with a potting material. This means that the TMR sensor chip and the applied buffer layer are additionally enclosed with a potting material. This process, known as potting, means that the entire sensor chip, including the buffer layer, is encapsulated in a protective material. One advantage is that the potting material provides comprehensive protection against environmental influences such as moisture, dust and chemical substances. In addition, it helps to cushion mechanical shocks and vibrations, which increases the structural integrity and reliability of the sensor. Potting also contributes to electrical insulation and protects sensitive electronic components from short circuits and other electrical damage.

### BRIEF DESCRIPTION OF THE DRAWINGS

Some examples of devices and/or methods are explained in more detail below merely by way of example with reference to the accompanying figures. In the figures:

FIG. 1 shows an example of a layer stack of a magnetoresistive sensor element according to one implementation;

FIG. 2 shows various stages of a structure of a sensor, starting with a sensor chip and ending with a complete sensor module; and

FIG. 3 shows an effect of mechanical stresses on the performance of a TMR sensor; and

FIGS. 4A-4G show various implementations of a sensor package according to the present disclosure.

### DETAILED DESCRIPTION

Some examples are now described in more detail with reference to the accompanying figures. However, further possible examples are not restricted to the features of these implementations that are described in detail. These may include modifications of the features, as well as equivalents and alternatives to the features. Furthermore, the terminology used herein to describe specific examples should not be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this should be understood as meaning that all possible combinations are disclosed, e.g., only A, only B, and also A and B, unless expressly defined otherwise in the individual case. “At least one of A and B” or “A and/or B” may be used as alternative wording for the same combinations. This applies equivalently to combinations of more than two elements.

If a singular form, e.g., “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it goes without saying that the terms “comprises”, “comprising”, “has” and/or “having” when used describe the presence of the stated features, whole numbers, steps, operations, processes, elements, components and/or a group thereof, but do not thereby exclude the presence or the addition of one or more other features, whole numbers, steps, operations, processes, elements, components and/or a group thereof.

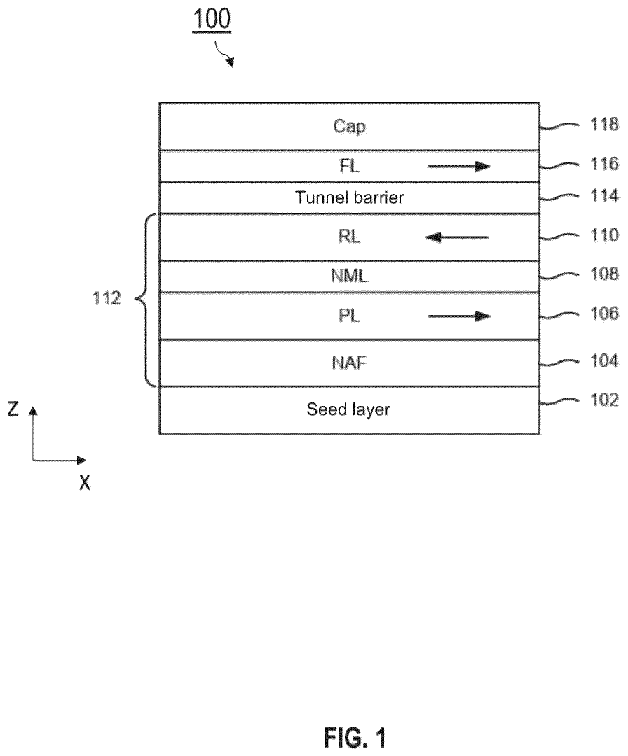

FIG. 1 shows an example of a layer stack of a magnetoresistive sensor element 100 according to one or more implementations.

The magnetoresistive sensor element 100 may be, for example, a TMR sensor element with a bottom-pinned spin-valve (BSV) configuration. In addition, the magnetoresistive sensor element 100 may be arranged on a semiconductor substrate (not illustrated) of a magnetoresistive sensor. When described in a Cartesian coordinate system with coordinate axes x, y and z which are perpendicular to one another in pairs, the layers of the layer stack extend laterally in an xy plane which is spanned by the x and y axes. Lateral dimensions (for example lateral distances, lateral cross-sectional areas, lateral surfaces, lateral extents, lateral shifts etc.) may therefore relate to dimensions in the xy plane and vertical dimensions may relate to dimensions in the z direction, perpendicular to the xy plane. The vertical extent of a layer in the z direction can therefore be referred to as the layer thickness, for example.

The layer stack of the magnetoresistive sensor element 100 comprises at least one reference layer with a reference magnetization (for example a reference direction in the case of GMR or TMR technology). The reference magnetization is a magnetization direction that provides a sensor direction corresponding to a sensor axis of the magnetoresistive sensor element 100. The reference layer and consequently the reference magnetization define a sensor plane. The sensor plane may be defined by the xy plane, for example. The x direction and the y direction can therefore be referred to as “in-plane” with respect to the sensor plane and the z direction can be referred to as “out-of-plane”with respect to the sensor plane.

Accordingly, in the case of a GMR sensor element or a TMR sensor element, the resistance of the magnetoresistive sensor element 100 is at a minimum if the magnetically free magnetization of a magnetically free layer points exactly in the same direction as the reference magnetization (for example the reference direction), and the resistance of the magnetoresistive sensor element 100 is at a maximum if the magnetically free magnetization of the magnetically free layer points exactly in the opposite direction to the reference magnetization. The orientation of the magnetically free magnetization of the magnetically free layer is variable when an external magnetic field is present. Therefore, the resistance of the magnetoresistive sensor element 100 can vary based on an influence of the external magnetic field on the magnetically free magnetization of the magnet-free layer.

From the bottom to the top, the magnetoresistive sensor element 100 may comprise an optional seed layer 102 which can be used to influence and/or optimize stack growth. In some implementations, the seed layer 102 may be composed of copper, tantalum, ruthenium or a combination thereof. In the example shown, a natural antiferromagnetic (NAF) layer 104 is formed on the seed layer 102 or is arranged elsewhere. The NAF layer 104 may be composed of platinum-manganese (PtMn), iridium-manganese (IrMn), nickel-manganese (NiMn) or the like. The layer thickness of the NAF may be in the range of 5 nanometers (nm) to 50 nm, for example.

In addition, a pinned layer (PL) 106 may be formed on the NAF layer 104 or arranged elsewhere. The pinned layer 106 may be composed of a ferromagnetic material, for example cobalt-iron (CoFe) or cobalt-iron-boron (CoFeB). Contact between the NAF layer 104 and the pinned layer 106 may cause an effect that is known as the exchange bias effect and causes the magnetization of the pinned layer 106 to be oriented in a preferred direction (for example in the x direction, as illustrated). The magnetization of the pinned layer 106 may be referred to as pinned magnetization. The pinned layer 106 may have a closed flux magnetization pattern (vortex) in the xy plane. This closed flux magnetization pattern of the pinned layer 106 may be produced when producing the magnetoresistive sensor element 100 and may be permanently fixed. Alternatively, the pinned layer 106 may have a linear magnetization pattern in the xy plane (for example a homogeneous orientation in one direction) that is permanently fixed.

The magnetoresistive sensor element 100 also comprises an non-magnetic layer (NML) which is referred to as a coupling intermediate layer 108. In one possible implementation, the coupling intermediate layer 108 may comprise, for example, ruthenium, iridium, copper, copper alloys or similar materials. Other materials (for example paramagnets) are likewise possible. A magnetic (for example ferromagnetic) reference layer (RL) 110 may be formed on the coupling intermediate layer 108 or arranged elsewhere. The thickness of the pinned layer 106 and of the magnetic reference layer 110 may be in the range of 1 nm to 10 nm.

Accordingly, the coupling intermediate layer 108 may be arranged between the pinned layer 106 and the magnetic reference layer 110 in order to spatially separate the pinned layer 106 and the magnetic reference layer 110 in the vertical direction. In addition, the coupling intermediate layer 108 may provide intermediate layer exchange coupling (for example antiferromagnetic Ruderman-Kittel-Kasuya-Yosida (RKKY) coupling) between the pinned layer 106 and the magnetic reference layer 110 in order to form an artificial antiferromagnet. Consequently, a magnetization of the magnetic reference layer 110 may be oriented and kept in a direction that is antiparallel or opposite to the magnetization of the pinned layer 106 (for example in the x direction, as illustrated). The magnetization of the magnetic reference layer 110 can be referred to as reference magnetization.

Since the NAF layer 104 is configured such that it orients and fixes the magnetization of the pinned layer 106 in a particular direction and the coupling intermediate layer 108 is configured such that it orients and fixes the magnetization of the magnetic reference layer 110 in an opposite direction, it can be the that the NAF layer 104 is configured to keep the magnetization of the pinned layer 106 (for example a fixed magnetization) in a first magnetic orientation and to keep the magnetization of the magnetic reference layer 110 (for example a fixed reference magnetization) in a second magnetic orientation. If, for example, the pinned layer 106 has a flux magnetization pattern (vortex magnetization pattern) closed in the clockwise direction in the xy plane, the magnetic reference layer 110 may have a flux magnetization pattern (vortex magnetization pattern) closed in the counterclockwise direction in the xy plane (or vice versa). In this manner, the magnetic reference layer 110 may have a permanent closed-flux magnetization pattern. Alternatively, the magnetic reference layer 110 may have a linear magnetization pattern in a particular direction in the xy plane if the pinned layer 106 has a linear magnetization pattern in an antiparallel direction. Therefore, the NAF layer 104, the pinned layer 106, the coupling intermediate layer 108 and the magnetic reference layer 110 form a magnetic reference layer system 112 of the magnetoresistive sensor element 100.

The magnetoresistive sensor element 100 additionally comprises a barrier layer 114 (for example a tunnel barrier) which is vertically arranged between the reference layer system 112 and a magnet-free layer 116. The barrier layer 114 may be formed, for example, on the magnetic reference layer 110 of the reference layer system 112 or arranged elsewhere, and the magnetically free layer 116 may be formed on the barrier layer 114 or arranged elsewhere.

The barrier layer 114 may be composed of a non-magnetic material. In some implementations, the barrier layer 114 may be an electrically insulating tunnel barrier layer. For example, the barrier layer 114 may be a tunnel barrier layer which is used to produce a TMR effect. The barrier layer 114 may be composed of magnesium oxide (MgO) or another material with similar properties.

The material of the magnetically free layer 116 may be an alloy of a ferromagnetic material, for example CoFe, CoFeB or NiFe. The magnetostriction constant of the magnetically free layer 116 can be adjusted using the iron content. The magnetically free layer 116 has a magnetically free magnetization that is variable when an external magnetic field is present. Therefore, the magnetically free layer 116 may be referred to as a sensor layer since changes in the magnetically free magnetization are used to determine a measurement variable. In addition, the magnetically free magnetization has a magnetic standard orientation (for example a linear or vortex magnetization) in a basic state. The basic state is a state in which the influence of the external magnetic field on the magnetically free layer 116 is not present or is negligibly small. In some implementations, the magnetoresistive sensor element 100 may comprise a magnetically free system containing a multiplicity of layers (for example two or more magnetically free layers) which act in combination as a magnetically free layer. In this case, the magnetically free layers of the magnetically free system are magnetically coupled to one another. The magnetically free system can therefore act as a magnetically free layer, but may also consist of a plurality of layers. The magnetically free system has a magnetically free magnetization, wherein the magnetically free magnetization is variable when the external magnetic field is present.

A covering layer 118, for example made of tantalum (Ta), tantalum nitride (TaN), ruthenium (Ru), titanium (Ti), titanium nitride (TiN), platinum (Pt) or the like, may be formed on the magnetically free layer 116 or arranged elsewhere in order to form an upper layer of the magnetoresistive sensor element 100.

The seed layer 102 may be used as a lower electrode or may establish electrical contact with a lower electrode (not illustrated) of the magnetoresistive sensor element 100. The covering layer 118 may establish electrical contact with an upper electrode (not illustrated) of the magnetoresistive sensor element 100. The barrier layer 114 may be configured such that electrons can tunnel between the reference layer system 112 and the magnetically free layer 116 if a bias voltage is applied to the electrodes of the magnetoresistive sensor element 100 (not illustrated) in order to produce a magnetoresistance effect (for example a TMR effect).

As mentioned above, FIG. 1 is used only as an example of a TMR sensor element. Other examples may differ from the description in FIG. 1. The number and arrangement of the components shown in FIG. 1 is an example. In practice, the TMR sensor element 100 may contain additional elements or layers, fewer elements, different elements or differently arranged elements than those shown in FIG. 1.

TMR sensor element 100 can be integrated as a TMR resistor on a TMR sensor chip. The TMR sensor chip can have more than one TMR resistor. For example, four TMR resistors can be integrated in a bridge circuit on the TMR sensor chip. A bridge circuit is a circuit configuration which consists of a plurality of electrical resistors which are arranged such that they form a bridge with the aim of enabling precise measurements of electrical resistance changes. In this context, the TMR resistors on the TMR sensor chip can be interconnected such that they form a bridge circuit, as a result of which they can react sensitively to changes in an external magnetic field.

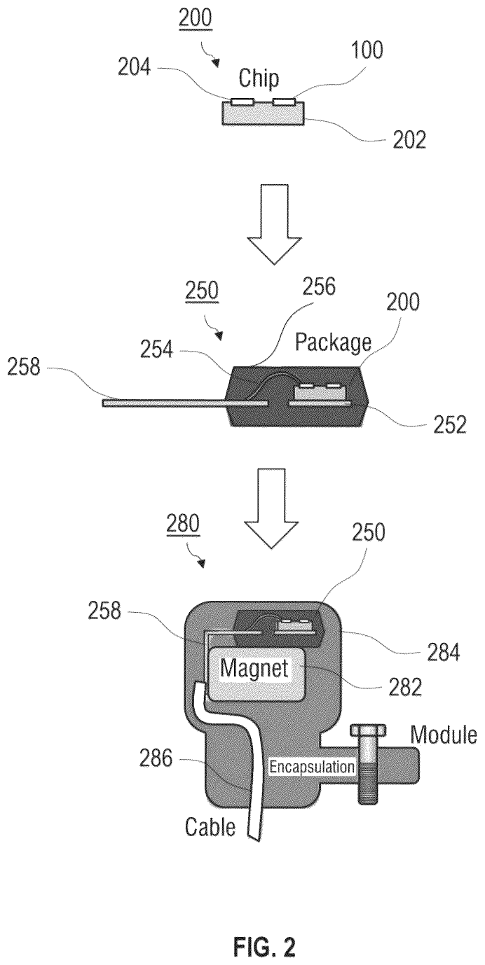

FIG. 2, in the upper part, schematically shows a TMR sensor chip 200 with an integrated TMR sensor element 100. TMR sensor element 100 is integrated on a substrate 202. The substrate 202 on which the TMR sensor element 100 is integrated may consist of a semiconductor substrate, such as silicon (Si) or gallium arsenide (GaAs) for example. The TMR sensor chip 200 further has one or more connector pads 204. A connector pad 204 is an area on the sensor chip 200 which is used as a contact point to produce electrical connections between the sensor chip 200 and external circuits. These pads 204 make it possible to transmit signals or supply power to the sensor chip 200.

FIG. 2, in the middle part, shows the chip 200 integrated into a package 250. The sensor package 250 is a protective case or a housing that encloses the chip 200. The package 250 can protect the chip 200 from mechanical damage, moisture, corrosion and other environmental influences. In addition, it allows an electrical connection of the chip 200 to external circuits and devices.

The sensor package 250 typically comprises a plurality of components. It comprises a carrier material 252 (e.g., lead frame) on which the chip 200 is mounted. The carrier material 252 may contain electrically conductive tracks, which connect the chip 200 to connectors 258 of the package 250. The sensor package 250 comprises the chip 200 which contains electronic circuits. The sensor package 250 comprises bond wires 254 which produce electrical connections between the connectors 204 on the chip 200 and connector pads 258 of the package 250. A potting material 256 or a case which surrounds the chip 200 can consist of plastic, ceramic or metal. It protects the chip 200 and the bond wires 254 from physical damage and environmental influences. The sensor package 250 comprises external connectors 258 (leads), via which electrical signals and power can be transmitted. These can be present in the form of pins, pads or other types of connection.

The lower part of FIG. 2 shows a sensor module 280, which, in addition to the sensor package 250, also contains other components such as a back bias magnet 282. The back bias magnet 282 can be a permanent magnet which is placed in the vicinity of the sensor package 250 to generate a constant magnetic field. This magnetic field can be used to influence and to stabilize the magnetic state of the TMR sensor elements 100. In a TMR sensor, electrical resistance is influenced by the relative orientation of the magnetization directions in two ferromagnetic layers which are separated by a thin insulating layer. The back bias magnet 282 can ensure that one of these layers is preset in a defined magnetization direction. This makes it possible for the sensor to precisely detect small changes in the external magnetic field, which are caused by the variable to be measured. The use of a back bias magnet can be useful to improve linearity and sensitivity of the sensor, as it stabilizes the magnetic working window and fixes the operating point of the sensor.

In the sensor module 280, the sensor package 250 is embedded in a larger housing 284 (encapsulation), which contains a cable connector 286 for an external connection, which is coupled to the connectors 258. The housing 284 protects the entire sensor module 280 from environmental influences and mechanical loads.

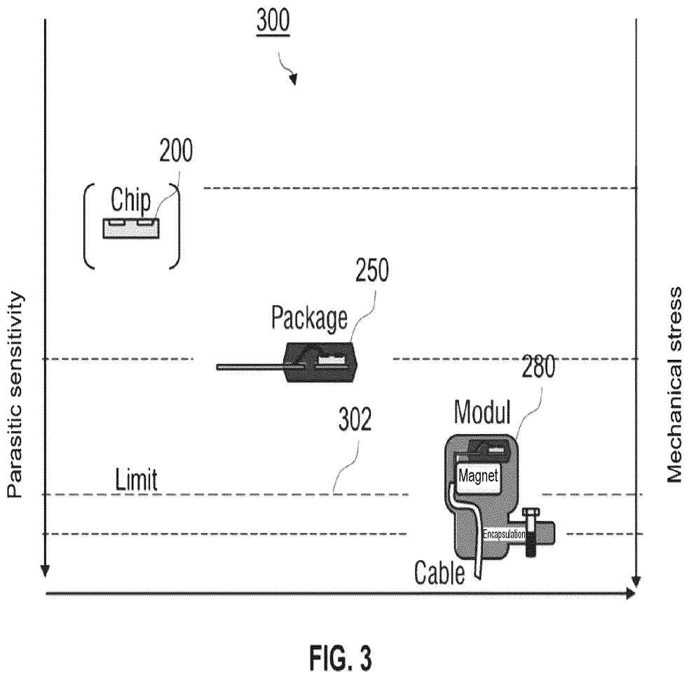

FIG. 3 shows the effect of mechanical stresses on the performance of a TMR sensor, represented by parasitic sensitivity as a function of a mechanical stress (e.g., shear stress oxy in MPa). Parasitic sensitivity refers to an undesirable property of a sensor, e.g., a speed sensor, in the case of which the sensor reacts to irrelevant or interfering influences that are not directly related to the intended measurement variable, the speed in this case. It is the sensitivity of the sensor to influences that can cause a faulty measurement or a distorted output of the sensor signal. In the context of TMR sensors, parasitic sensitivity means that the sensor reacts sensitively to mechanical stresses, temperature fluctuations or magnetic fields that are not directly related to the speed to be measured. This parasitic sensitivity can lead to deviations or errors in the measurement data, which can impair the accuracy and reliability of the sensor. A low value for parasitic sensitivity is desirable because it indicates that the sensor is largely immune to such interference and reliably detects the intended measurement variable.

FIG. 3 illustrates how the mechanical load in various stages of sensor construction—from the pure chip via the package up to the complete module—affects the sensor performance.

Chip: No mechanical stress is specified here, which indicates an ideal or stress-free initial situation.

Package: With the integration of the chip 200 into a package 250, the mechanical shear stress increases in the example shown. The parasitic sensitivity is in a negative range, but above a critical specification limit value.

Module: When the package 250 is further integrated into the complete module 280 with additional components, such as a magnet, the mechanical stress increases further. This leads to a further deterioration of the parasitic sensitivity, which falls below the specified limit value.

The dashed line 302 marks a lower parasitic sensitivity specification limit value, below which the sensor performance is considered unacceptable. FIG. 3 clarifies that increasing mechanical stresses due to the packaging and module integration process can significantly worsen the performance of the sensor, which necessitates particular measures for stress reduction.

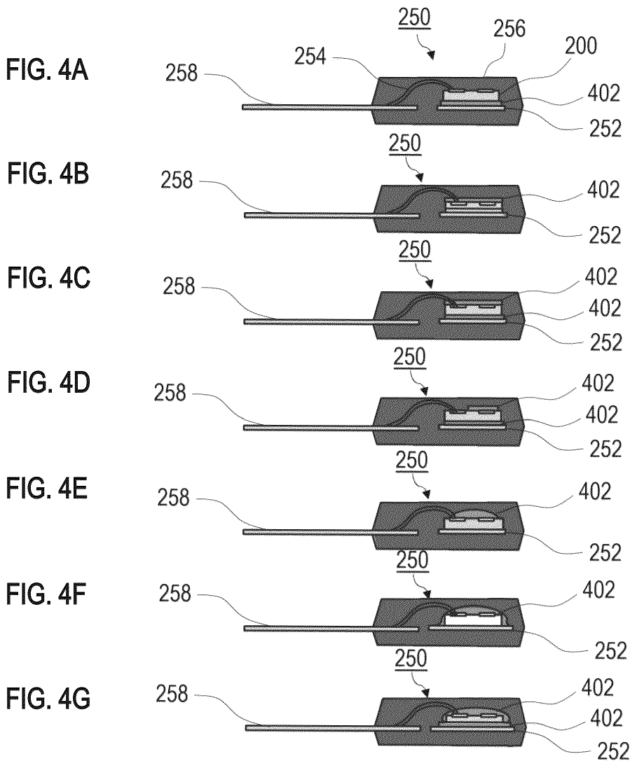

FIGS. 4A-4G shows various example implementations of sensor packages 250 according to the present disclosure. All sensor packages 250 that are shown comprise a TMR sensor chip 200 and a buffer layer 402 having a modulus of elasticity of less than 1 GPa at a temperature of 20° C. In the example implementations shown, the buffer layer 402 is arranged above and/or below the TMR sensor chip 200. The buffer layer 402 can have a modulus of elasticity of less than 0.5 GPa at 20° C., such as 0.2 GPa or 0.1 GPa for example. Silicone-based materials, such as silicone adhesives for example, have such low moduli of elasticity. The buffer layer 402 can have a thickness in the range of 50-150 μm, such as 100 μm for example.

There are several examples of silicone adhesives that can be used in semiconductor manufacturing. Dow Corning 3140 RTV Coating is a silicone adhesive that is used in the electronics and semiconductor industry. It offers excellent moisture resistance and is suitable for the protective coating of electronic components. Another silicone adhesive is Shin-Etsu KE-45 RTV, which is known for its high resistance to extreme temperatures and its dielectric properties. Momentive RTV 157 can be used for the encapsulation and protection of electronic components and offer high mechanical damping and protection from environmental influences. Also, 3M 3145 RTV Mil-A-46146 is a silicone adhesive which was developed specifically for use in electronics. It is resistant to high temperatures and offers good mechanical damping. Loctite SI 5970 can be used in semiconductor manufacturing and offer high flexibility and temperature resistance. Wacker Elastosil E43 is a silicone adhesive that can be used in the semiconductor industry. It offers a good balance between flexibility and strength and is resistant to extreme temperatures.

In FIG. 4A, the TMR sensor chip 200 is mounted on a lead frame 252. Between the lead frame 252 and the TMR sensor chip 200 is the buffer layer 402, which functions as a stress buffer. The buffer layer 402 extends over the entire underside of the TMR sensor chip 200. The chip is electrically connected by bond wires 254 which connect the chip to external connectors 258. This arrangement offers protection and damping from below, in that it absorbs mechanical stresses and thus improves the performance and longevity of the sensor. Spacers (not shown) can be embedded into the buffer layer 402. This means that small structural elements can be integrated within the buffer layer 402 to ensure a constant spacing between TMR sensor chip 200 and lead frame 252. The spacers can ensure an even thickness of the buffer layer 402. For example, the spacers can be of spherical design and have a diameter of 50-150 μm. The spacers can be formed from silicon oxide, which increases the mechanical stability and offers consistent damping.

In FIG. 4B, the buffer layer 402 is arranged on a top side of the TMR sensor chip 200. The buffer layer 402 (with a low modulus of elasticity) is therefore arranged between the TMR sensor chip 200 and the potting material 256 (with a larger modulus of elasticity) of the sensor package 250. The buffer layer 402 extends flat over the entire top side of the TMR sensor chip 200. This arrangement offers protection and damping from above, in that it effectively absorbs mechanical stresses that are acting on the top side of the chip. Here too, spacers (not shown) can be embedded into the buffer layer 402 to ensure an even layer thickness and improve the mechanical load capacity.

In FIG. 4C, the TMR sensor chip 200 is likewise mounted on the lead frame 252. Flat buffer layers 402 are located both between the lead frame 252 and the TMR sensor chip 200 and on the top side of the TMR sensor chip 200. The buffer layers 402 extend over the entire underside or top side of the TMR sensor chip 200. This arrangement offers additional protection and damping both from above and from below, which further reduces mechanical stresses. As a result, the mechanical integrity of the TMR sensor chip 200 is improved and its sensitivity to external forces is reduced.

FIG. 4D shows a similar setup to FIG. 4c, but the upper buffer layer 402 does not extend over the entire top side of the TMR sensor chip 200 here. The lateral extent of the upper buffer layer 402 is smaller than the lateral extent of the TMR sensor chip 200. The heat dissipation may be improved as a result, for example. Due to the partial coverage, a portion of the surface of the TMR sensor chip 200 is exposed, as a result of which the heat that is generated can be dissipated more efficiently. This can improve the thermal stability of the sensor and contribute to ensuring that sensor performance remains reliable even at higher operating temperatures.

FIG. 4E shows a variant in which, as in FIG. 4B, the buffer layer 402 is arranged only on the top side of the TMR sensor chip 200, but in a dome-shaped structure which can offer additional space for mechanical deformations. This can allow better adaptation to mechanical stresses by distributing the loads onto the sensor chip more evenly. In turn, the chip 200 is mounted on the lead frame 252 and connected to the connectors 258 by bond wires 254.

In FIG. 4F, the buffer layer 402 is likewise dome-shaped, however, it encloses the side surfaces and top side of the TMR sensor chip 200. This arrangement offers more comprehensive protection, as the buffer layer protects not only the top side, but also the side surfaces of the chip. The TMR sensor chip 200 is mounted on the lead frame 252 and arranged in the dome-shaped buffer layer 402 in the process. This design can further increase the structural integrity and resistance of the sensor to mechanical influences.

FIG. 4G shows an example implementation which represents a combination of FIG. 4A and FIG. 4F. A first flat buffer layer 402 is located between the lead frame 252 and the TMR sensor chip 200. A second dome-shaped buffer layer 402 encloses the side surfaces and top side of the TMR sensor chip 200. This double buffer layer arrangement can maximize protection from mechanical stresses from all sides and offer improved thermal stability at the same time.

A process of producing the sensor package 250 can comprise various techniques, such as dispensing, screen printing and jetting. On the top side of the TMR sensor chip 200, the buffer layer 402 can be realized at wafer level or after die attach. On the underside of the TMR sensor chip 200, the buffer layer 402 can likewise be realized at the wafer level or on a chip carrier prior to die attach, wherein the buffer layer 402 can function as die attach material. Lithographic methods at the wafer level can also be used, both on the top side and on the underside, for example in that materials that can be photostructured are used.

Materials that can be used for the buffer layer 402 have moduli of elasticity that are considerably lower than those of encapsulation and die attach materials which are typically used for the packaging, such as epoxy-based potting compounds and die attach adhesives for example. One example of such a material shows a modulus of elasticity of less than 1 GPa after curing, even at low temperatures down to −20 . . . −40° C. These materials can be silicone-based and can contain spacers to ensure a defined thickness of the die attach adhesive, if die attach adhesive is used below the chip 200. The spacers are particles of a predefined size, such as particles of glass, silicon or ceramic for example, wherein spherical geometries can be preferred.

One advantage of this method of production consists in the sensor chip 200 being exposed to significantly lower mechanical stresses during further processing, such as during forming for example or in the event of mechanical loads in the field. This can lead to improved performance and a lower temperature sensitivity of the sensor. In addition, this approach may represent an inexpensive measure compared to a complete redesign of the chip.

The present disclosure relates to sensor packages which contain TMR (tunneling magnetoresistance) sensors. A buffer layer is proposed to protect the sensitive magnetoresistive layers from mechanical loads and to improve the performance and service life of the sensors. The buffer layer has a low modulus of elasticity, preferably less than 1 GPa, and can consist of silicone-based materials. The buffer layer is fitted on and/or under the TMR sensor chip to reduce mechanical stresses. During production, the buffer layer can either be applied to a wafer before individual TMR sensor chips are separated from each other or after mounting the sensor chip on a lead frame.

The aspects and features described in connection with a particular one of the previous examples may also be combined with one or more of the other examples to replace an identical or similar feature of this other example or to introduce the feature additionally into the other example.

Furthermore, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Furthermore, in other examples, a single step, a single function, a single process or a single operation may include and/or be broken into multiple substeps, subfunctions, subprocesses or suboperations.

If some aspects have been described in the preceding sections in connection with a device or system, these aspects should also be understood as a description of the corresponding method. In this case, for example, a block, a device or a functional aspect of the device or the system may correspond to a feature, such as a method step, of the corresponding method. Correspondingly, aspects described in connection with a method should also be understood as a description of a corresponding block, a corresponding element, a property or a functional feature of a corresponding device or of a corresponding system.

The following claims are hereby incorporated into the detailed description, each claim being independent as a separate example. It should also be noted that-although a dependent claim in the claims refers to a particular combination with one or more other claims-other examples may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:
Aspect 1: A sensor package, comprising: a tunneling magnetoresistance (TMR) sensor chip; and a buffer layer having a modulus of elasticity of less than 1 gigapascal (GPa) at a temperature of 20° C., wherein the buffer layer is fitted on or under the TMR sensor chip.
Aspect 2: The sensor package as recited in Aspect 1, wherein the buffer layer has a modulus of elasticity of less than 0.5 GPa at 20° C.
Aspect 3: The sensor package as claimed in any of Aspects 1-2, wherein the buffer layer comprises a silicone-based material.
Aspect 4: The sensor package as claimed in any of Aspects 1-3, wherein the buffer layer comprises a silicone adhesive.
Aspect 5: The sensor package as claimed in any of Aspects 1-4, wherein the buffer layer has a thickness in a range of 50-150 μm.
Aspect 6: The sensor package as claimed in any of Aspects 1-5, wherein spacers are embedded into the buffer layer.
Aspect 7: The sensor package as recited in Aspect 6, wherein the spacers are spherical.
Aspect 8: The sensor package as recited in Aspect 6, wherein the spacers comprise silicon oxide.
Aspect 9: The sensor package as claimed in any of Aspects 1-8, wherein the TMR sensor chip is arranged on a lead frame and the buffer layer is arranged between the lead frame and the TMR sensor chip.
Aspect 10: The sensor package as claimed in any of Aspects 1-9, further comprising: a potting material within which the TMR sensor chip and the buffer layer are potted, wherein the modulus of elasticity of the buffer layer is lower than a modulus of elasticity of the potting material.
Aspect 11: The sensor package as recited in Aspect 10, wherein the buffer layer is arranged between the TMR sensor chip and the potting material.
Aspect 12: The sensor package as recited in Aspect 10, wherein the buffer layer is arranged on the TMR sensor chip, and the TMR sensor chip is arranged on a lead frame.
Aspect 13: The sensor package as recited in Aspect 12, wherein the buffer layer is a first buffer layer is arranged on the TMR sensor chip, and wherein the sensor package further comprises a second buffer layer arranged below the TMR sensor chip, between the TMR sensor chip and the lead frame.
Aspect 14: The sensor package as claimed in any of Aspects 1-13, wherein a lateral extent of the buffer layer is smaller than a lateral extent of the TMR sensor chip.
Aspect 15: A method for producing a sensor package, comprising: providing a tunneling magnetoresistance (TMR) sensor chip; and providing a buffer layer on or under the TMR sensor chip, wherein the buffer layer has a modulus of elasticity of less than 1 GPa at a temperature of 20° C.
Aspect 16: The method as recited in Aspect 15, wherein, when providing the buffer layer, the buffer layer is applied directly to a wafer before individual TMR sensor chips are separated from each other.
Aspect 17: The method as claimed in any of Aspects 15-16, wherein, when providing the buffer layer, the buffer layer is applied after the TMR sensor chip has been attached to a substrate or to a lead frame.
Aspect 18: The method as claimed in any of Aspects 15-17, wherein providing the buffer layer comprises dispensing, jetting, or screen printing of the buffer layer.
Aspect 19: The method as claimed in any of Aspects 15-18, further comprising: potting the TMR sensor chip and the buffer layer within a potting material.
Aspect 20: A system configured to perform one or more operations recited in one or more of Aspects 1-19.
Aspect 21: An apparatus comprising means for performing one or more operations recited in one or more of Aspects 1-19.

1. A sensor package comprising:
a tunneling magnetoresistance (TMR) sensor chip; and
a buffer layer having a modulus of elasticity of less than 1 gigapascal (GPa) at a temperature of 20° C., wherein the buffer layer is fitted on or under the TMR sensor chip.

2. The sensor package as claimed in claim 1, wherein the buffer layer has a modulus of elasticity of less than 0.5 GPa at 20° C.

3. The sensor package as claimed in claim 1, wherein the buffer layer comprises a silicone-based material.

4. The sensor package as claimed in claim 1, wherein the buffer layer comprises a silicone adhesive.

5. The sensor package as claimed in claim 1, wherein the buffer layer has a thickness in a range of 50-150 μm.

6. The sensor package as claimed in claim 1, wherein spacers are embedded into the buffer layer.

7. The sensor package as claimed in claim 6, wherein the spacers are spherical.

8. The sensor package as claimed in claim 6, wherein the spacers comprise silicon oxide.

9. The sensor package as claimed in claim 1, wherein the TMR sensor chip is arranged on a lead frame and the buffer layer is arranged between the lead frame and the TMR sensor chip.

10. The sensor package as claimed in claim 1, further comprising:
a potting material within which the TMR sensor chip and the buffer layer are potted,
wherein the modulus of elasticity of the buffer layer is lower than a modulus of elasticity of the potting material.

11. The sensor package as claimed in claim 10, wherein the buffer layer is arranged between the TMR sensor chip and the potting material.

12. The sensor package as claimed in claim 10, wherein the buffer layer is arranged on the TMR sensor chip, and the TMR sensor chip is arranged on a lead frame.

13. The sensor package as claimed in claim 12, wherein the buffer layer is a first buffer layer arranged on the TMR sensor chip, and
wherein the sensor package further comprises a second buffer layer arranged below the TMR sensor chip, between the TMR sensor chip and the lead frame.

14. The sensor package as claimed in claim 1, wherein a lateral extent of the buffer layer is smaller than a lateral extent of the TMR sensor chip.

15. A method for producing a sensor package, comprising:
providing a tunneling magnetoresistance (TMR) sensor chip; and
providing a buffer layer on or under the TMR sensor chip, wherein the buffer layer has a modulus of elasticity of less than 1 GPa at a temperature of 20° C.

16. The method as claimed in claim 15, wherein, when providing the buffer layer, the buffer layer is applied directly to a wafer before individual TMR sensor chips are separated from each other.

17. The method as claimed in claim 15, wherein, when providing the buffer layer, the buffer layer is applied after the TMR sensor chip has been attached to a substrate or to a lead frame.

18. The method as claimed in claim 15, wherein providing the buffer layer comprises dispensing, jetting, or screen printing of the buffer layer.

19. The method as claimed in claim 15, further comprising:
potting the TMR sensor chip and the buffer layer within a potting material.
